(19) United States
(12) Patent Application Publication
(10) Pub. No.: US 2008/0111160 A1
(43) Pub. Date: May 15, 2008

(54) SEMICONDUCTOR DEVICE AND INTERCONNECT STRUCTURE

(75) Inventors: Yuan-Sheng Chiang, Hsinchu City (TW); Hsuan-Hsu Chen, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 11/954,182

(22) Filed: Dec. 11, 2007

Related U.S. Application Data
(62) Division of application No. 11/163,812, filed on Oct. 31, 2005.

(51) Int. Cl. H01L 27/148

(52) U.S. Cl. 257/233

(57) ABSTRACT

A semiconductor device is described, including a substrate, a transistor, a hard mask layer and an anti-reflection layer. The substrate includes a first area and a second area, wherein the second area includes a photosensing area. The transistor is disposed on the substrate in the first area and the hard mask layer over the substrate in the second area. The anti-reflection layer is disposed between the hard mask layer and the substrate.

### CROSS-REFERENCE TO RELATED APPLICATION

This application is a divisional of an application Ser. No. 11/163,812, filed Oct. 31, 2005, now pending. The entirety of each of the above-mentioned patent applications is hereby incorporated by reference herein and made a part of this specification.

### BACKGROUND OF THE INVENTION

1. Field of the Invention

The present invention relates to integrated circuit structures. More particularly, the present invention relates to a semiconductor device of sensor type that has a higher sensitivity, to an interconnect structure structurally correlated with the semiconductor device, and to their respective fabricating methods.

2. Description of the Related Art

Photodiode image sensors have been widely spread recently. A photodiode image sensor includes an array of sensing units (pixels), each of which includes a reset transistor and a photosensing area including a PN-diode coupled to the reset transistor.

On the other hand, the source/drain (S/D) regions and gates of MOS transistors on the sensor chip are usually formed with self-aligned metal silicide (salicide) thereon. To prevent salicide from forming on the photosensing area, a salicide block (SAB) is usually formed covering the photosensing area before the salicide process.

Conventionally, the SAB is formed by firstly depositing on the substrate a silicon oxide (SiO) layer and then removing the SiO layer outside the photosensing area with dry etching. However, since the SiO material on the gate spacer of a transistor cannot be removed completely with dry etching, an extra spacer is formed covering a portion of the S/D regions and adversely affecting the later salicide process.

Moreover, when the SAB is a SiO layer, the light perpendicularly or obliquely incident to the photosensing area has quite a proportion being reflected by the SiO layer, so that the sensitivity of the image sensor is difficult to improve.

### SUMMARY OF THE INVENTION

Accordingly, this invention provides a semiconductor device of sensor type that has a higher sensitivity.

This invention also provides a method for fabricating a semiconductor device without forming an extra spacer covering a portion of the S/D regions.

The semiconductor device of this invention includes a semiconductor substrate, a transistor, a hard mask layer and an anti-reflection layer. The substrate includes a first area and a second area, wherein the second area includes a photosensing area. The transistor is disposed on the substrate in the first area and the hard mask layer over the substrate in the second area. The anti-reflection layer is disposed between the hard mask layer and the substrate.

According to various embodiments of the above semiconductor device, the hard mask layer may include SiO, silicon carbide (SiC), borophosphosilicate glass (BPSG), phosphosilicate glass (PSG), fluorosilicate glass (FSG) or polysilicon (poly-Si), and the thickness thereof may be 100-1000 Å. The anti-reflection layer may include silicon nitride (SiN) or silicon oxynitride (SiON), and the thickness thereof may be 400-2000 Å. A salicide layer may be further disposed on the S/D regions and gate of the transistor, wherein the salicide may include tungsten silicide (WSi), titanium silicide (TiSi), cobalt silicide (CoSi), molybdenum silicide (MoSi), nickel silicide (NiSi), palladium silicide (PdSi) or platinum silicide (PtSi). A sacrificial layer may be further disposed between the anti-reflection layer and the substrate, wherein the material of the sacrificial layer may be SiO and the thickness of the same may be 10-300 Å.

The method for fabricating a semiconductor device of this invention is described below. A semiconductor substrate including a first area and a second area is provided, wherein the first area is disposed with a transistor on the substrate and the second area includes a photosensing area. An anti-reflection layer is formed over the substrate, and then a patterned hard mask layer covering the second area is formed on the anti-reflection layer. A wet-etching step is then conducted using the patterned hard mask layer as a mask to remove the anti-reflection layer outside the second area.

According to various embodiments of the above method, the patterned hard mask layer may be formed with the following steps. A hard mask material is formed on the anti-reflection layer, and then a photoresist layer is formed on the hard mask material. Lithography and etching steps are conducted to pattern the hard mask material, and the photoresist layer is then removed. The hard mask material may be formed through plasma-enhanced chemical vapor deposition (PECVD), and may be SiO, SiC, BPSG, PSG or FSG or include poly-Si. When the hard mask material is poly-Si, the above method may further include a step of removing the patterned hard mask layer after the anti-reflection layer outside the second area is removed. In addition, the etchant used in the wet etching step may be hot phosphoric acid. The anti-reflection layer may be formed through PECVD. The method may further include a step of forming a sacrificial layer over the substrate before the anti-reflection layer is formed, wherein the sacrificial layer may be formed though thermal oxidation or PECVD. The method may further include a step of forming a salicide layer on the S/D regions and the gate of the transistor after the anti-reflection layer is patterned, wherein the patterned hard mask layer and the patterned anti-reflection layer together serve as an SAB.

Since the SAB formed on the photosensing area includes an anti-reflection layer and a hard mask layer, the light incident to the photosensing area is reflected less as compared with the prior art that forms SiO as the SAB. Hence, the sensitivity of the image sensor is enhanced. Moreover, since wet etching is utilized to remove the anti-reflection layer outside the second area in the above method of this invention, an extra spacer is not formed on the sidewall of a gate covering a portion of the S/D region.

This invention further provides an interconnect structure that is structurally related to the above semiconductor device of this invention. The interconnect structure includes a substrate with a conductive part thereon, a dielectric layer on the substrate, an etching stop layer between the dielectric layer and the substrate, and a via plug. The via plug is electrically connected with the conductive part, including a first part in the dielectric layer and a second part in the etching stop layer, wherein the width of the second part is larger than that of the first part.

According to various embodiments of the interconnect structure, the material of the etching stop layer may be SiN, and that of the via plug may be tungsten (W) or aluminum (Al). The above interconnect structure may further include a barrier layer between the via plug and each of the dielectric layer and the etching stop layer, wherein the material of the barrier layer may be Ti, TiN or tantalum nitride (TaN).

This invention also provides a method for fabricating the above interconnect structure, including the following steps. A substrate with a conductive part thereon is provided, and then an etching stop layer is formed on the substrate. A dielectric layer is formed on the etching stop layer, and then a first opening is formed in the dielectric layer to expose a portion of the etching stop layer over the conductive part. A wet etching step is conducted using the dielectric layer as a mask to form a second opening in the etching stop layer, wherein the second opening exposes the conductive part and is wider than the first opening. A via plug is formed in the first and the second openings.

According to various embodiments of the above method, the first opening may be formed with the following steps. A photoresist layer is formed on the dielectric layer. Lithography and etching steps are conducted to pattern the dielectric layer, and then the photoresist layer is removed. The via plug may be formed through an atomic level deposition (ALD) process. The etchant used in the wet etching step may be hot phosphoric acid. Moreover, the method may further include a step of forming a barrier layer on the internal surfaces of the first and second openings after the second opening is formed but before the via plug is formed, wherein the barrier layer may be formed through PECVD, metal organic chemical vapor deposition (MOCVD) or ionized metal plasma (IMP) deposition.

Since the portion of the via plug in the etching stop layer is wider than the portion in the dielectric layer, the contact area between the via plug and the conductive part is increased lowering the contact resistance. Moreover, since the etching step of the first opening is stopped on the etching stop layer, the conductive part under the etching stop layer is not damaged. In addition, because the second opening is formed through wet etching, it is formed wider than the first opening due to the undercut effect to expose more area of the conductive part and increase the contact area between the via plug and the conductive part lowering the contact resistance.

It is to be understood that both the foregoing general description and the following detailed description are exemplary, and are intended to provide further explanation of the invention as claimed.

### BRIEF DESCRIPTION OF THE DRAWINGS

FIGS. 1A and 1B illustrate cross-sectional views of two semiconductor devices according to two embodiments of this invention.

FIGS. 2A-2D illustrate, in a cross-sectional view, a process flow of fabricating a semiconductor device according to an embodiment of this invention.

FIGS. 3A and 3B illustrate cross-sectional views of two interconnect structures according to two embodiments of this invention.

FIGS. 4A-4D illustrate, in a cross-sectional view, a process flow of fabricating an interconnect structure according to an embodiment of this invention.

### DESCRIPTION OF THE PREFERRED EMBODIMENTS

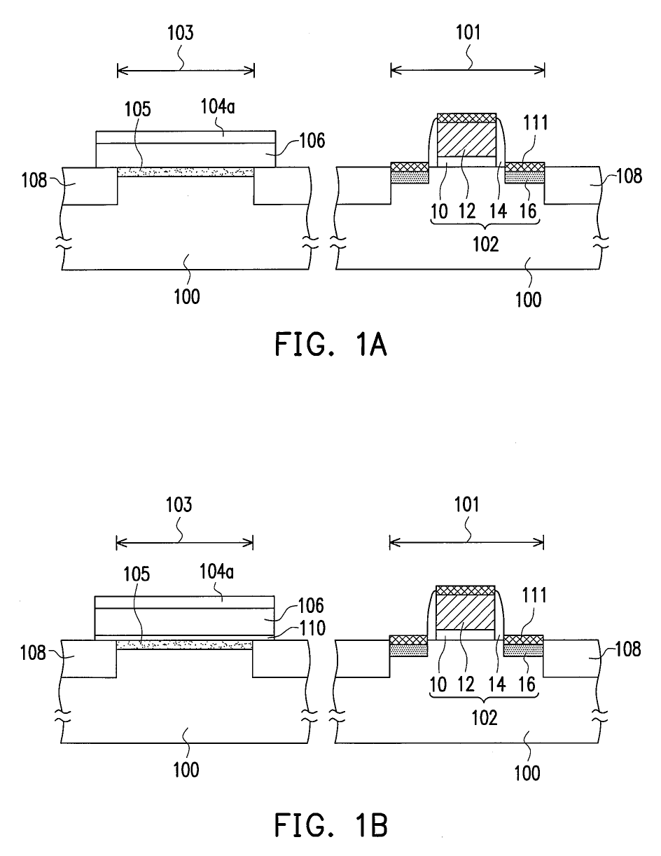

FIG. 1A illustrates a cross-sectional view of a semiconductor device according to an embodiment of this invention. The semiconductor device includes a substrate 100, a transistor 102, a hard mask layer 104a and an anti-reflection layer 106. The substrate 100 includes a first area 101 and a second area 103 that are defined by an isolation structure 108, such as an STI layer. The second area 103 includes a photosensing area, in which a doped region 105 of different conductivity type is formed in the substrate 100 to form a PN diode. The doped region 105 may alternatively be formed in a well of different conductivity type in the substrate 100 to form a PN diode.

The transistor 102 is disposed on the substrate 100 in the first area 101, and may be a MOS transistor including gate dielectric 10, a gate 12, a spacer 14 and two S/D regions 16. The hard mask layer 104a is disposed over the substrate 100 in the second area 103, including a material different from that of the anti-reflection layer 106, such as SiO, SiC, BPSG, PSG, FSG or poly-Si, and preferably having a thickness of 100-1000 Å. The anti-reflection layer 106 is between the hard mask layer 104a and the substrate 100, possibly including SiN or SiON and having a thickness of 400-2000 Å. A salicide layer 111 possibly including WSi, TiSi, CoSi, MoSi, NiSi, PdSi or PtSi may be further disposed on the S/D regions 16 and the gate 12 of the transistor 102.

Since the anti-reflection layer 106 and the hard mask layer 104a are sequentially stacked on the second area 103, the light perpendicularly or obliquely incident to the photosensing area is reflected less as compared with the prior art using SiO to form the SAB. Therefore, the sensitivity of the photodiode image sensor can be enhanced.

FIG. 1B illustrates a cross-sectional view of a semiconductor device according to another embodiment of this invention. The semiconductor device is different from the above one in that a sacrificial layer 110 is further disposed between the anti-reflection layer 106 and the substrate 100 to improve the adhesion of the anti-reflection layer 106. The sacrificial layer 110 may include SiO, and may have a thickness of 10-300 Å.

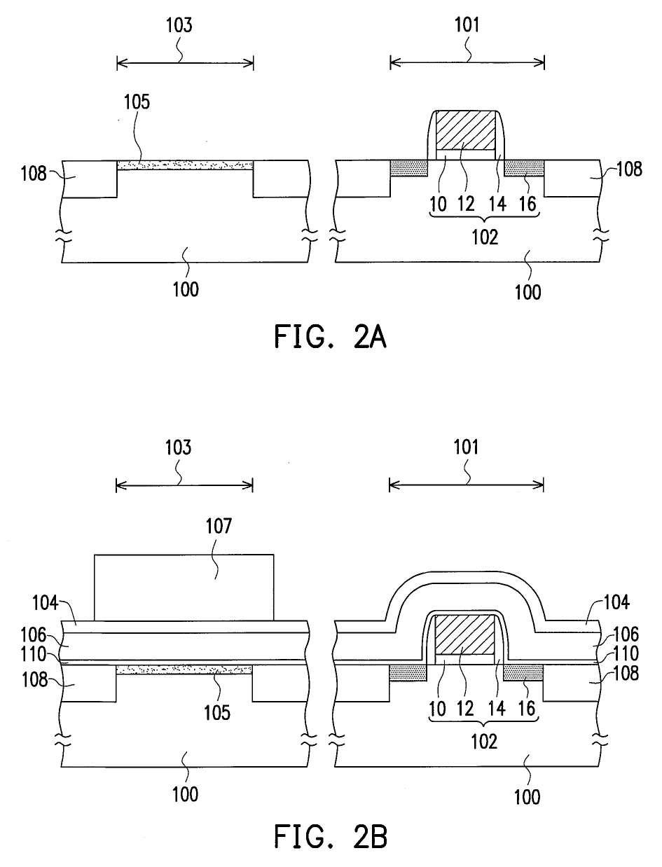

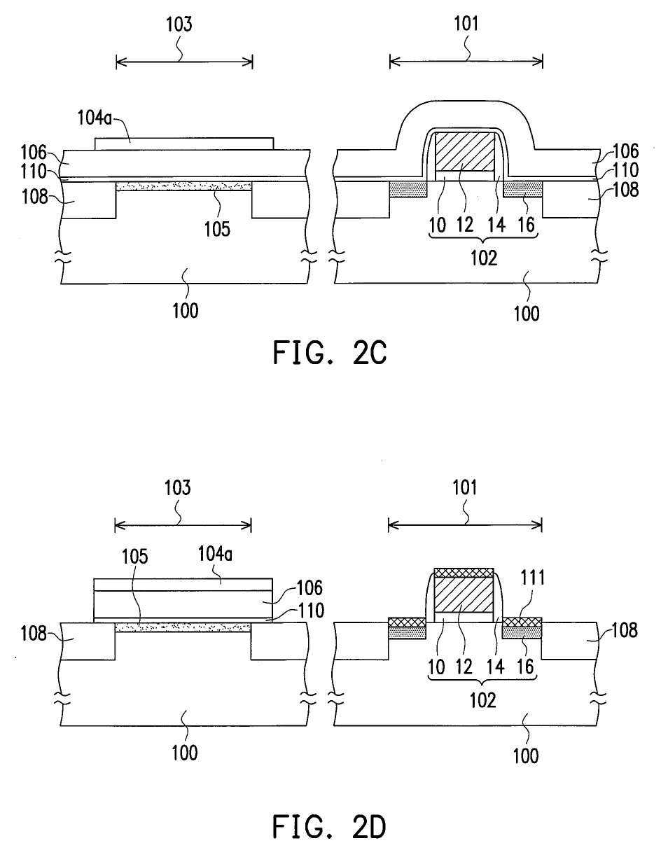

FIGS. 2A-2D illustrate a process flow of fabricating a semiconductor device as shown in FIG. 1B according to an embodiment of the invention.

Referring to FIG. 2A, a substrate 100 that includes a first area 101 and a second area 103 defined by an isolation structure 108 is provided, wherein the first area 101 is disposed with a transistor 102 and the second area 103 is a photosensing area.

Referring to FIG. 2B, a sacrificial layer 110 is formed on the substrate 100, possibly through thermal oxidation or PECVD, to enhance the adhesion of the anti-reflection layer 106 formed later. Then, the anti-reflection layer 106 and a hard mask material 104 are sequentially formed on the sacrificial layer 110, wherein the anti-reflection layer 106 or the hard mask material 104 may be formed through PECVD, and possible materials of the same have been described above. In another embodiment, a sacrificial layer is not formed, while the anti-reflection layer 106 is formed directly on the substrate 100. Then, a patterned photoresist layer 107 covering the second area 103 is formed on the hard mask material 104 with a lithography process.

Referring to FIG. 2C, a dry or wet etching step is conducted with the patterned photoresist layer 107 as a mask to etch the hard mask material 104 and form a patterned hard mask layer 104a. After the photoresist layer 107 is removed, a wet etching step is conducted using the hard mask layer 104a as a mask to removed the anti-reflection layer 106 and the sacrificial layer 110 outside the second area 103, as shown in FIG. 2D. The wet etching step may be conducted by sequentially removing the exposed anti-reflection layer 106 and the exposed sacrificial layer 110 respectively with hot phosphoric acid and dilute hydrofluoric acid. A salicide process is then conducted, with the hard mask layer 104a, the anti-reflection layer 106 and the sacrificial layer 110 together serving as an SAB, to form a salicide layer 111 on the gate 12 and the S/D regions 16 of the transistor 102.

It is noted that since a wet etching step is conducted to remove the anti-reflection layer 106 and the sacrificial layer 110 outside the second area 103, the exposed anti-reflection layer 106 and sacrificial layer 110 can be removed completely. Hence, no extra spacer is formed on sidewalls of the gate 12 partially covering the S/D regions 16.

It is also noted that when the hard mask material 104 is poly-Si, the hard mask layer 104a should be removed after the anti-reflection layer 106 and the sacrificial layer 110 are patterned. When the hard mask material 104 is a dielectric material like SiO, SiC, BPSG, PSG or FSQ the hard mask layer 104a is not necessary to remove but can serve as a part of the inter-layer dielectric (ILD).

It is further noted that the principle of the above fabricating process may also be applied to the fabrication of an interconnect structure as follows.

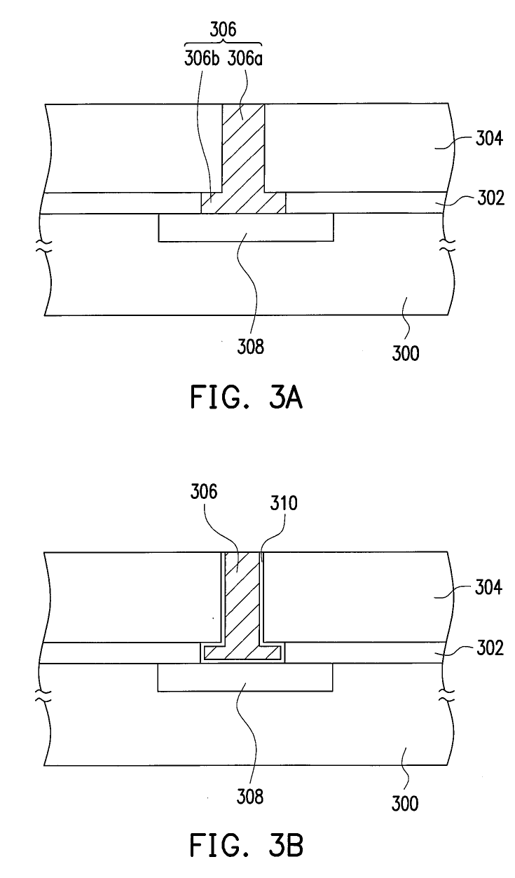

FIG. 3A illustrates a cross-sectional view of an interconnect structure according to an embodiment, which includes a substrate 300 having thereon a conductive part 308, an etching stop layer 302 on the substrate 300, a dielectric layer 304 on the etching stop layer 302, and a via plug 306. The conductive part 308 may be a conductive line or a part of a semiconductor device. The dielectric layer 340 may include SiO, BPSQ PSG or FSC, and the etching stop layer 302 may include SiN. The via plug 306 is electrically connected with the conductive part 308, including a first part 306a in the dielectric layer 304 and a second part 306b in the etching stop layer 302 wider than the first part 306a. The material of the via plug 306 may be tungsten or aluminum. Since the part (306b) of the via plug 306 contacting with the conductive part 308 is wider, the contact area is larger causing a lower contact resistance.

FIG. 3B illustrates an interconnect structure of another embodiment, which is different from the above one in that a barrier layer 310 is further disposed between the via plug 306 and each of the dielectric layer 304 and the etching step layer 302 to separate them and prevent a spike effect. The material of the barrier layer 310 may be Ti, TiN or TaN.

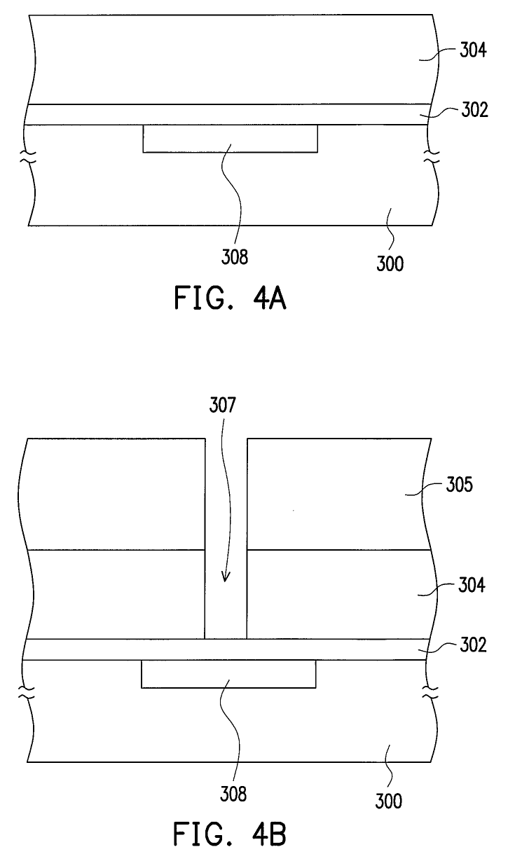

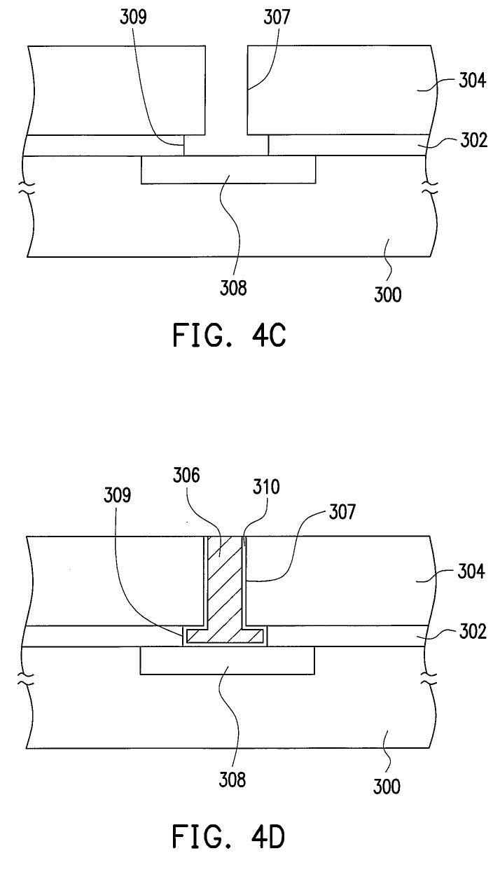

FIGS. 4A-4D illustrate a process flow of fabricating an interconnect structure as shown in FIG. 3B according to an embodiment of the invention. Referring to FIG. 4A, a substrate 300 with a conductive part 308 thereon is provided, and then an etching stop layer 302 is formed on the substrate 300 possibly through PECVD. A dielectric layer 304 is then formed on the etching stop layer 302, possibly through PECVD.

Referring to FIG. 4B, a patterned photoresist layer 305 having therein an opening over the conductive part 308 is formed on the dielectric layer 304 with a lithography step. An etching step, normally a dry etching step, is conducted using the photoresist layer 305 as a mask to form in the dielectric layer 304 an opening 307 that exposes a portion of the etching stop layer 302 over the conductive part 308. Since the etching step of the opening 307 is stopped on the etching stop layer 302, the conductive part 308 is not damaged by the etching.

Referring to FIG. 4C, after the photoresist layer 305 is removed, a wet etching step is conducted using the dielectric layer 304 as a mask to form in the etching stop layer 302 an opening 309 that exposes the conductive part 308, wherein the opening 309 is wider than the opening 307 due to the undercut effect. The etchant used in the wet etching step may be hot phosphoric acid.

Referring to FIG. 4D, a barrier layer 310 is formed on the internal surfaces of the openings 307 and 309, so that the via plug 306 formed later can be separated from the dielectric layer 304 and the etching stop layer 302 to prevent a spike effect. The barrier layer 310 may be formed through PECVD, MOCVD or ionized metal plasma (IMP) deposition. Then, a via plug 306 is formed in the openings 307 and 309, possibly through atomic level deposition (ALD). Since the opening 309 is wider than the opening 307, the contact area between the via plug 306 and the conductive part 308 is increased lowering the contact resistance between them.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A semiconductor device, comprising:
a semiconductor substrate including a first area and a second area, wherein the second area comprises a photosensing area;
a transistor on the substrate in the first area;
a hard mask layer over the substrate in the second area; and
an anti-reflection layer between the hard mask layer and the substrate.

2. The semiconductor device of claim 1, wherein the hard mask layer comprises SiO, SiC, BPSG, PSG, FSG or poly-Si.

3. The semiconductor device of claim 1, wherein the hard mask layer has a thickness of 100-1000 Å.

4. The semiconductor device of claim 1, wherein the anti-reflection layer comprises SiN or SiON.

5. The semiconductor device of claim 1, wherein the anti-reflection layer has a thickness of 400-2000 Å.

6. The semiconductor device of claim 1, further comprising a salicide layer on a source/drain region and a gate of the transistor.

7. The semiconductor device of claim 6, wherein the salicide layer comprises WSi, TiSi, CoSi, MoSi, NiSi, PdSi or PtSi.

8. The semiconductor device of claim 1, further comprising a sacrificial layer between the anti-reflection layer and the substrate.

9. The semiconductor device of claim 8, wherein the sacrificial layer comprises SiO.

10. The semiconductor device of claim 8, wherein the sacrificial layer has a thickness of 10-300 Å.

11. An interconnect structure, comprising:
a substrate having a conductive part thereon;
a dielectric layer on the substrate;
an etching stop layer between the dielectric layer and the substrate; and
a via plug electrically connected with the conductive part, including a first part in the dielectric layer and a second part in the etching stop layer, wherein a width of the second part is larger than a width of the first part.

12. The interconnect structure of claim 11, wherein the etching stop layer comprises SiN.

13. The interconnect structure of claim 11, wherein the via plug comprises tungsten (W) or aluminum (Al).

14. The interconnect structure of claim 11, further comprising a barrier layer between the via plug and each of the dielectric layer and the etching stop layer.

15. The interconnect structure of claim 14, wherein the barrier layer comprises Ti, TiN or TaN.
